(19) United States
(12) Patent Application Publication
(10) Pub. No.: US 2009/0110805 A1
(43) Pub. Date: Apr. 30, 2009

(54) Apparatus and Method for Controlling the Surface Temperature of a Substrate in a Process Chamber

(75) Inventors: Johannes Kaeppeler, Wurselen (DE); Walter Franken, Eschweiler (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: AIXTRON INC., Sunnyvale, CA (US)

(21) Appl. No.: 12/298,032

(22) PCT Filed: Apr. 17, 2007
(86) PCT No.: PCT/EP2007/053745

§ 371 Date: Oct. 21, 2008

(30) Foreign Application Priority Data
Apr. 21, 2006 (DE) 10 2006 018 514.5

(51) Int. Cl. C23C 16/52

(52) U.S. Cl. 427/8; 118/712

(57) ABSTRACT

The invention relates to a method of controlling the surface temperature of a substrate (9) resting on a substrate holder (2) borne by a substrate holder support (1) on a dynamic gas cushion (8) formed by a gas stream in a process chamber (12) of a CVD reactor, wherein heat is introduced into the substrate (9) at least partly by thermal conduction via the gas cushion. To reduce lateral deviations of the surface temperature of a substrate from a mean, it is proposed that the gas stream forming the gas cushion (8) be formed by two or more gases (17, 18) having different specific thermal conductivities and the composition be varied as a function of a measured substrate temperature.

The invention relates to a method for controlling the surface temperature of a substrate resting on a substrate holder carried by a substrate holder carrier on a dynamic gas cushion formed by a gas stream, in a process chamber of a CVD reactor, heat being supplied to the substrate at least partly by thermal conduction via the gas cushion.

The invention also relates to an apparatus for carrying out the method according to one or more of the preceding claims, comprising a process chamber, a substrate holder carrier disposed therein, one or more substrate holders, a heater for heating up the substrate holder carrier, an optical temperature measuring device for measuring the surface temperatures of the substrates resting on the substrate holders, and comprising a gas supply line for supplying a gas stream to produce a dynamic gas cushion between the substrate holder carrier and a substrate holder.

An apparatus of the generic type and a method of the generic type are described in DE 10056029 A1. This document describes a CVD reactor for depositing III-V semiconductor layers on III-V substrates. The substrates lie on substrate holders, which have the form of circular-cylindrical disks. These substrate holders lie in a satellite-like arrangement on a substrate holder carrier. The substrate holder carrier has bearing recesses, which receive the substrate holders. Emerging from the bottom of the bearing recesses are gas streams, which keep the substrate holder suspended on a gas cushion. The substrate holders are set in rotation by a corresponding direction of the gas stream emerging from the nozzles at the bottom. In the case of such a CVD reactor, it is not only possible for the substrate holders to rotate in relation to the substrate holder carrier. It is also provided that the substrate holder carrier itself rotates about its own axis.

The substrate holder carrier, and similarly the substrate holders, may consist of graphite. There is in principle the need to keep the surface temperature of the substrates that are resting on the substrate holder constant over the entire surface of the substrates. The surface temperature is measured by means of a pyrometer. For this purpose, the process chamber ceiling, lying opposite the substrate holder carrier, has an opening. The pyrometer is connected to a control device. This control device determines firstly the average surface temperature of the substrate. This is intended to lie within a specific setpoint range. The heat for producing the surface temperature of the substrate is supplied from below via the substrate holder carrier. For this purpose, the latter is heated from below. The heat is transferred to the substrate holder both by means of thermal radiation and by means of thermal conduction via the gap forming the dynamic gas cushion. This heat is conducted from the underside of the substrate holder to the upper side of the substrate holder, on which the substrate is lying. It is only in an ideal case that the substrate lies with its full surface area in contact with the surface of the substrate. In reality, the substrate often only rests on the substrate holder at the edge or at the center. This is a consequence of thermally or structurally caused warping of the substrate.

By variation of the flow rate of the gas stream which forms the gas cushion, the height of the gas cushion is influenced. As a consequence of this height adjustment, the thermal conductivity of this gas gap is influenced. By changing the gas stream, the heat transfer to the substrate can consequently be influenced. By means of this method, known in principle from DE 10056029 A1, the average surface temperature of the substrate can indeed be delicately influenced. The lateral variation in temperature on the surface, that is to say temperature inhomogeneities and, in particular, horizontal gradients, can only be influenced to a restricted extent by this method.

DE 101 33 914 A1 discloses an apparatus for depositing layers on substrates in which a multiplicity of substrate holders lie in cup-shaped recesses of a substrate holder carrier. The substrate holders are each carried by a gas cushion.

A method for controlling the temperature for depositing a material is already known from DE 696 29 980 T2. The substrate lies above a cooling block. Between the substrate and the cooling block there is a gap, which is flushed with gases of different thermal conductivities.

DE 691 17 824 T2 describes a method in which the rear side of a substrate is flushed with a mixture of argon and hydrogen.

U.S. Pat. No. 5,683,759 describes a method for depositing polycrystalline diamonds on a substrate, a substrate holder having annular grooves of various depths.

WO 2005/121417 A1 discloses a CVD apparatus in which the substrates rest on a rotatable substrate holder. The substrate holder rests on a gas cushion.

The invention is based on the object of reducing more effectively the lateral deviations of the surface temperature of a substrate from a mean value.

The object is achieved by the invention specified in the claims.

Each claim represents an independent solution for achieving the object and can be combined with each other claim.

It is provided first and foremost that the gas stream forming the gas cushion is formed by two or more gases with different specific thermal conductivities. The thermal conductivity of the dynamic gas cushion is varied by the composition of this gas stream. The thermal conductivity may also be varied (additionally) by increasing the flow rate. When there is an increase in the gas stream, and the accompanying increase in the size of the gas cushion, the surface temperature falls substantially uniformly over the entire diameter of the substrate holder. The variation in quality of the temperature profile over the surface area, and in particular over the diameter, is changed only slightly by this measure. It has surprisingly been found that the changing of the thermal conductivity of the gas forming the gas cushion makes it possible to influence the temperature profile as such. This is so since it has been found that, as the conductivity of the gas cushion increasingly rises, the temperature at the center of the surface of the substrate holder rises more than at the edge. Consequently, a fine setting of the variation in the temperature on the substrate holder surface is possible by variation of the thermal conductivity of the dynamic gas cushion. The possibility according to the invention of finely setting the thermal conductivity consequently provides the possibility of influencing the temperature without changing the thickness of the gas cushion. This is of advantage in particular whenever the two very different heat-conducting gases also have very different viscosities. It is also provided that the substrate holder has a thermal conductivity, or the substrate holder and the bearing recess are of such a shape, that, when only one of the two gases is used, the surface temperature of the substrate holder has a lateral inhomogeneity that can be compensated, and in particular overcompensated, by changing the composition. The thermal conductivity of the substrate holder may have a radial inhomogeneity. However, it is provided that the substrate holder has rotational symmetry with respect to the thermal conductivity. The surface areas facing each other and delimiting the gas cushion, of the underside of the substrate holder on the one hand and the bottom surface of the bearing recess on the other hand, also have a special structure, in particular a rotationally symmetrical structure. These two surface areas may have a shape that deviates from the shape of a plane. The gas cushion may have different thicknesses at different radial positions. For example, it may be provided that, when nitrogen is used as the carrier gas, with poorer conduction than hydrogen, the substrate holder surface temperature is lower at the center than at the edge. If, on the other hand, hydrogen is used as the gas producing the gas cushion, the surface temperature of the substrate holder is higher at the center than at the edge. Suitable mixing of the two gases with one another allows the variation in temperature over a transverse path on the substrate holder to be set in such a way that the deviations of the temperatures in the individual radial positions from the mean value are minimized. Ideally, this allows a flat temperature profile to be set on the substrate holder surface. The latter also applies to the surface temperature of a substrate resting on the substrate holder. If this substrate becomes warped during the process, the associated local changes in the heat transporting properties from the substrate holder to the substrate can be compensated by correspondingly changing the gas composition. If, for example, the center of the substrate lifts itself from the substrate holder because of thermal bending of the substrate, the heat transfer at the center can be increased by variation of the gas composition. In an analogous way, it is possible to compensate for the reduced temperature transfer at the edge if the edges of the substrate lift themselves from the substrate holder surface because of warping of the substrate. Such effects can be optimally compensated if, when only a highly heat-conducting gas is used, the central region of the substrate holder is warmer than the edge region or, when only a poorly heat-conducting gas is used, the central region of the substrate holder is colder than the edge region. Substrate holders of heat-conducting properties that are locally different in the axial direction may also be used. For instance, the heat-conducting property in the axial direction may be different at the center than at the edge of the substrate holder. This also applies to the heat-radiating properties, which are responsible for the energy transfer by way of thermal radiation. These may also be different at different radial positions. The heat-radiating properties are substantially surface properties. It is therefore provided that the surface of the bottom of the bearing recess and the surface of the underside of the substrate holder can have locally different heat-radiating properties. In a preferred refinement, however, the substrate holders have different material thicknesses in the radial direction. For example, the substrate holder may be thinner at the center than at the edge. For this purpose, the underside of the substrate holder may have a curvature. A concave curvature and a convex curvature may be provided. In an analogous way, the bottom of the bearing recess may also be either convexly or concavely curved. However, it is also provided that the substrate holder has a stepped recess on its underside.

The apparatus for carrying out the method substantially corresponds to that described by DE 10056029 A1. Furthermore, the method according to the invention may also be carried out by a variation of the gas streams to vary the height of the gas cushion. Therefore, the disclosure content of DE 10056029 is incorporated in full in this application.

The apparatus for carrying out the method has a heater arranged under the substrate holder carrier. This may be a resistance heater. This heats the substrate holder carrier. The substrate holder is heated by thermal conduction and thermal radiation. The surface temperature of the substrate resting on the substrate holder is continually measured. Since the substrate holder is rotated, an average temperature is measured. However, the radial dependence of the temperature can be established. In principle, one pyrometer is adequate for measuring the temperature if the substrate holder carrier is rotated about its axis. The measured values of the pyrometer are fed to a control device. This control device controls mass flowmeters, which control the gas composition of the gas stream that forms the gas cushion. In this case, the overall gas flow per unit of time is generally kept constant, so that the height of the gas cushion remains constant. However, it is also possible that, in addition, by variation of the overall flow, the height of the gas cushion is varied.

Exemplary embodiments of the invention are explained below on the basis of accompanying drawings, in which:

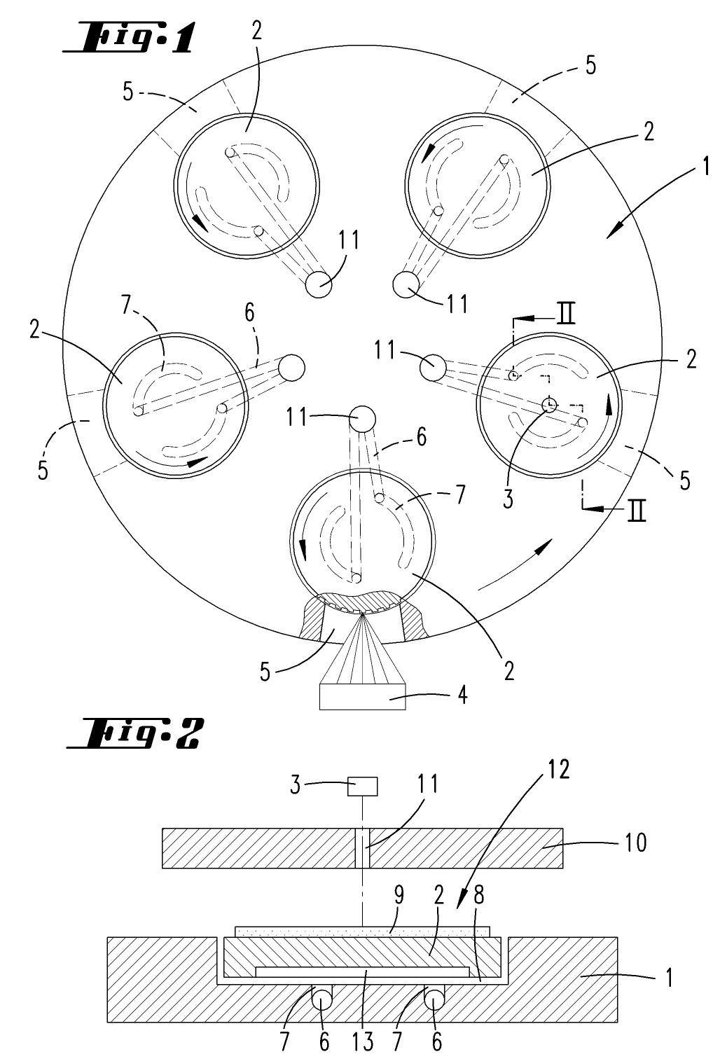

FIG. 1 shows the plan view of a substrate holder carrier, with a total of five substrate holders lying in bearing recesses, for respectively receiving a substrate;

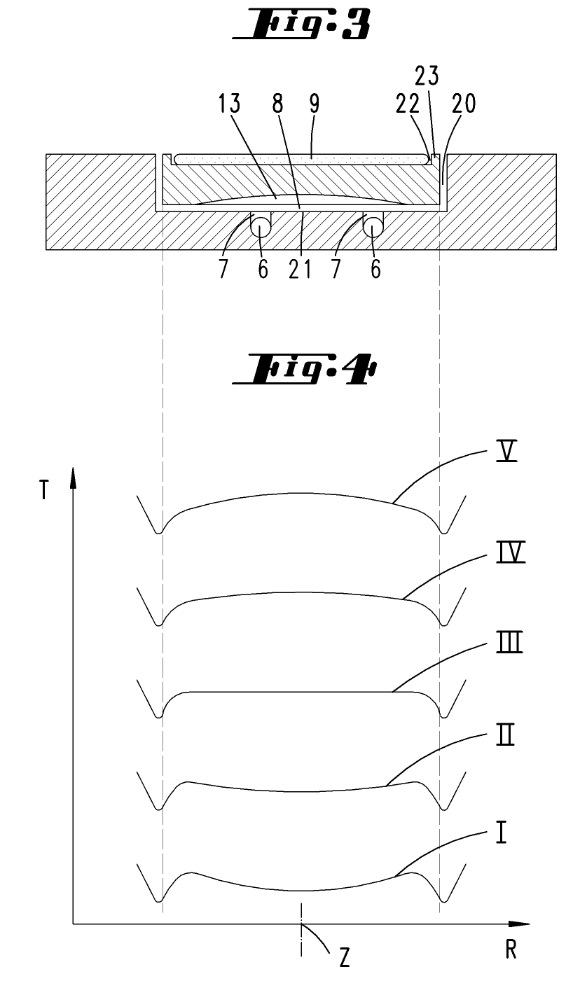

FIG. 2 schematically shows a partial section through the process chamber along the line II-II;

FIG. 3 shows a representation according to FIG. 2 of an alternative configuration of a substrate holder;

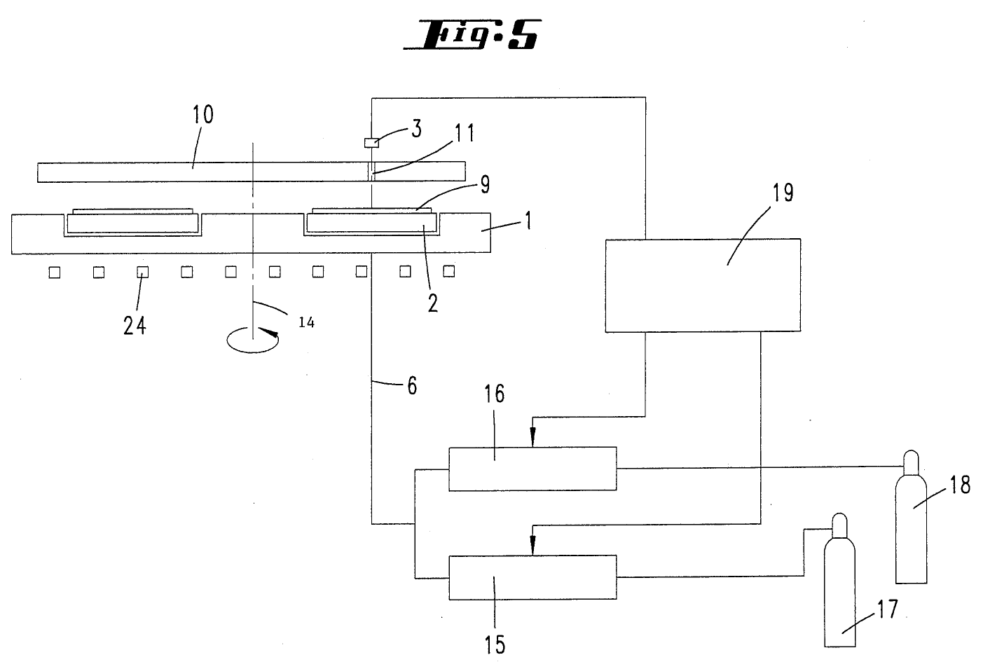

FIG. 4 qualitatively shows the variations in temperature over a path across the substrate, in the case of different gas compositions of the gas stream forming the dynamic gas cushion, and

FIG. 5 shows the peripheral equipment for the reactor in a schematic representation.

The method according to the invention is carried out in a process chamber 12 of a CVD reactor. This process chamber 12 is located between a horizontally extending substrate holder carrier 1, which has a circular outline and can be rotationally driven about its axis 14. Located parallel and above the substrate holder carrier 1 is the process chamber ceiling 10. The process chamber is located between the ceiling 10 and the substrate holder carrier 1. The substrate holder carrier 1 is heated from below by means of a resistance heater 24. Provided on the upper side of the substrate holder carrier 1 are a total of five bearing recesses 20. A circular disk-shaped substrate holder 2 lies in each of the cup-shaped bearing recesses 20. In the bottom 21 of the bearing recess 20 there are spiral grooves 7, into which gas supply lines 6 open out. The gas emerging from the spiral grooves 7 raises the substrate holder 2 and supports it on a dynamic gas cushion 8. The gases emerge from the spiral groove 7 with a particular direction, suitable for rotationally driving the substrate holder 2 so that it rotates about its own axis. On each of the substrate holders 2 there lies a substrate 9. The entire process chamber is disposed in a reactor housing (not represented) and is hermetically sealed from its surroundings, so that the process chamber 12 can be evacuated.

Process gases are required for carrying out the CVD process and these are introduced into the process chamber 12 through supply lines that are not represented. These process gases may contain organometallic compounds. They may also contain hydrides. There may also be metal chlorides. A single-crystal layer is to be deposited on the surface of the substrates 9. This may comprise materials of the main group IV or materials of the main groups III and V or materials of the main groups II and VI. The substrate 9 may consist of any suitable material. It may be a non-conductor or a semiconductor. It is only in an ideal case that lattice-matched layers are deposited on the single-crystalline surface of the substrate. It is only in an ideal case that the deposited layers and the substrate have the same coefficients of thermal expansion. As a rule, the layers are not 100% lattice-matched. Individual layers also have different coefficients of thermal expansion. In particular, the layers have greater or smaller coefficients of thermal expansion. This has the consequence that, when there is a change in temperature of the substrate in the region of the layers or the boundary surface, stresses occur and lead to warping of the substrate. The depositing of layers that are not lattice-matched may also lead to distortions and consequently to warpages of the substrate 9. Depending on the degree to which the lattice constants or the coefficients of thermal expansion differ, the center of the substrate 9 may warp upward or downward. Since the depositing processes are carried out at different temperatures inside the process chamber 12, the warping of the substrate 9 may also be reversed during a process, so that in one phase of the process only the central region of the substrate 9 lies in contact with the surface of the substrate holder 2 and in another phase of the process only the edge of the substrate 9 lies in contact with the surface of the substrate holder 2. This has the consequence that the heat flux from the surface of the substrate holder 2 to the substrate 9 differs laterally and varies over time.

If the process chamber 12 is only heated from below, a vertical temperature gradient forms there. This means that the temperature in the gas phase above the substrate 9 decreases with increasing distance from the substrate holder 2. Because of the lack of contact of the substrate 9 with the surface of the substrate holder 2 at individual points, here there is reduced heat transfer from the substrate holder 2 to the substrate 9. This has the consequence that certain regions of the substrate 9 are colder than other regions. This is not desired. What is desired, rather, is a surface temperature that remains the same over the entire surface area of the substrate 9, so that the temperature gradient in the horizontal direction is minimal. The isotherm directly over the surface of the substrate 9 should be as flat as possible. The substrate surface should ideally lie on one isotherm.

The heat transfer from the substrate holder carrier 1 to the substrate holder 2 takes place substantially via the dynamic gas cushion 8. Here, both the thermal radiation from the bottom 21 of the bearing recess 20 to the underside of the substrate holder 2 and the thermal conduction via the heat-conducting gas that forms the gas cushion 8 play a part.

The heat transfer by radiant heat can be influenced by different configurations of both the surface of the bottom 21 and the underside of the substrate holder 2. The heat transfer by thermal conduction can be varied by variation of the height of the dynamic gas cushion 8. For this purpose, the overall gas flow through the supply line 6 may be increased or decreased. However, with these measures it is not possible during the process to influence the lateral variation in the isotherms directly over the substrate 9 or the lateral temperature gradient of the surface temperature of the substrate 9.

According to the invention, it is provided that this is effected by means of variation of the composition of the gas that produces the dynamic gas cushion 8. Two gases 17, 18 that differ greatly in their specific thermal conductivity are used. For example, highly heat-conducting hydrogen 17 may be mixed with poorly heat-conducting nitrogen 18. For this purpose, mass flow controllers 15, 16 serve individually for each of the two gases 17, 18. However, other gas mixtures, in particular suitable noble gases such as argon, helium, etc., may also be used. The two different gases 17, 18 are conducted into the bearing recesses 20 by a common supply line 6. By variation of the composition of the gases, which takes place by means of the mass flow controllers 15 and 16, the thermal conductivity of the gas cushion 8 can be varied. The height of the gas cushion 8 at the same time remains substantially unchanged. A control device 19 is provided for setting the gas flows 15, 16. This control device 19 gets its input data from a pyrometer 3, which measures the substrate surface temperature through an opening 11. An average surface temperature is measured, since the substrate holder 2 rotates. As a result of the rotation of the substrate holder carrier 1 itself, one substrate holder 2 after the other moves under the opening 11. Since said opening has the same radial distance from the axis of rotation 14 as the axis of rotation of the substrate holder 2, a variation in temperature across the substrate is measured, as represented for example in FIG. 4.

By suitable structural or by suitable material selection, the substrate holder 2 can be configured in such a way that, when only a poorly heat-conducting gas 18 is used, the edge region of the substrate holder surface becomes hotter than the central region. This is represented in FIG. 4 by the curve I. If the mixing ratio of the gas is changed to the extent that, by adding more hydrogen 17 and reducing nitrogen 18, the thermal conductivity of the gas is increased, the central region of the surface of the substrate holder 1 is heated up to a greater degree. This is indicated by the curve II and is attributable to a surprising effect. A further increase in the thermal conductivity of the gas cushion 8 then leads to the temperature of the substrate holder surface being substantially the same over the entire radial extent—as represented in curve III. This is a desired state, when the substrate 9 rests in the ideal way with its surface area on the surface of the substrate holder 2.

By further changing the mixing ratio toward a high conductivity of the gas, a variation in temperature as represented by the curve IV is achieved. If only hydrogen 17 flows through the supply line 6, a variation in temperature such as that represented by curve V can be achieved. A variation in temperature of the substrate holder surface as represented by curves I and II is necessary whenever the substrate 9 rests only with its central region on the surface of the substrate holder 2. Then, the temperature of the substrate holder 2 must be higher in the edge region in order to compensate there for the reduced thermal conduction to the substrate 9. The variations in temperature according to curves IV and V are of significance when the substrate 9 rests only with the edge region on the surface of the substrate holder 2. Then, the reduced thermal conduction in the central region must be compensated by a higher surface temperature.

In the case of the substrate holder represented in FIG. 2, the underside of the substrate holder 2 has a cutout 13. Here, this is a central, cup-shaped cutout 13, which leads to an increase in the height of the gas cushion 8. This has the consequence of a reduced amount of heat being transported from the bottom 21 to the substrate holder 2 by thermal conduction. The accompanying inhomogeneity of the surface temperature can be compensated by a corresponding composition of the gases.

In the case of the exemplary embodiment represented in FIG. 3, this cutout 13 is represented as a depression. The bottom of the depression 13 goes over steplessly into the planar annular face of the underside of the substrate holder 2.

It is considered to be particularly advantageous that, with a combination of the variation of the gas composition and a simultaneous increase in the gas pressure, not only the variation in the surface temperature but also the absolute value of the surface temperature can be influenced. This makes it possible to lower or raise the edge temperature with respect to the central temperature around a constant mean value, it being possible for the edge temperature of the substrate holder 2 to lie both above and below the central temperature of the substrate surface. The variation in temperature on the substrate holder surface is ideally set by the control device 19, by means of variation of the mass flows 15, 16, such that, as far as possible, the substrate surface has the same temperature at each point.

All features disclosed are (in themselves) pertinent to the invention. The disclosure content of the associated/accompanying priority documents (copy of the prior patent application) is also hereby incorporated in full in the disclosure of the application, including for the purpose of incorporating features of these documents in claims of the present application.

1. A method for controlling a surface temperature of at least one substrate (9) resting on a substrate holder (2) lying in a bearing recess (20) of a substrate holder carrier (I) and carried on a dynamic gas cushion (8) formed by a gas stream, in a process chamber (12) of a CVD reactor, heat being supplied to the substrate (9) at least partly by thermal conduction via the gas cushion, the surface temperature of the substrate being measured at a multiplicity of points on a surface of the substrate and, characterized in that to reduce discrepancies between these temperatures and a mean value, a heat-conducting, property of the gas cushion is changed by the gas stream that forms the gas cushion (8) between a bottom surface of the bearing recess (20) and an underside of the substrate (2) being formed by two or more gases (17, 18) with different specific thermal conductivities, a composition of the gas stream being varied according to the surface temperatures measured, the thermal conductivity of the substrate holder (2) being chosen, and the underside of the substrate (2) and the bottom surface of the bearing recess (20) being configured, such that, when only one of the two gases (17, 18) is used, the surface temperature of the substrate has a rotationally symmetrical lateral inhomogeneity that is compensated or overcompensated by changing the composition of the gas stream.

2. The method according to claim 1 characterized in that, by variation of the gas stream composition, lateral variation in temperature on the surface of the substrate holder (2) is influenced in such a way that the temperature on the substrate surface is constant over substantially the entire substrate surface.

3. The method according to claim 2 characterized in that, when only one gas (17, 18) is used, in particular a highly heat-conducting gas, a central region of the substrate holder (2) is warmer than an edge region thereof.

4. The method according to claim 2 characterized in that, when only one gas (17, 18) is used, in particular a poorly heat-conducting gas, a central region of the substrate holder (2) is colder than an edge region thereof.

5. The method according to claim 2 characterized in that, by variation of individually controlled gas streams; producing the gas cushions (8), of individual substrate holders (2) of a multiplicity of substrate holders (2) associated with the substrate holder carrier (I), heights of the gas cushions (8) are regulated such that measured mean values thereof lie within a given temperature window.

6. The method according to claim 1 characterized in that the substrate holder (2) is rotationally driven by the gas stream.

7. The method according to claim 1 characterized in that the substrate holder carrier (I) is rotationally driven about a central axis.

8. The method according to claim 2 characterized in that a temperature measurement is performed through an opening (11) in a process chamber ceiling (10).

9. The method according to claim 8 characterized in that substrate surface temperatures are measured during an entire treatment process and the composition of the gas stream forming the dynamic gas cushion (8) is varied during, the treatment as a function of radially measured variation in temperature of the substrate temperature.

10. The method according to claim 2 characterized in that the substrate holder (2) has heat-conducting properties that are different in an axial direction and/or heat-radiating properties that are different at different radial positions.

11. The method according to claim 1 characterized in that the gas cushion (8) has a height that is lower at its edge than at its center.

12. An apparatus comprising a process chamber (12), a substrate holder carrier (I) disposed therein, at least one substrate holder (2), a heater for heating up the substrate holder carrier (I), an optical temperature measuring device (3) for measuring a surface temperature of at least one substrate (9) resting on the substrate holder (2) in each case at points on a surface of the substrate that are different from one another, a gas supply line (6) for supplying a gas stream to produce a dynamic gas cushion (8) between an underside of the substrate holder (2) and a bottom surface of a bearing recess (20) of tile substrate holder carrier (I) in which the substrate holder (2) is mounted, a gas mixing device (15, 16, 17, 18) associated with the gas supply line (6) and in which a composition of the gas stream made up of two gasses, a poorly heat-conducting gas and a highly heat-conducting gas, can be set according to a radial temperature profile of the substrate surface temperature obtained by the temperature measuring device (3), the substrate holder (2) having such a thermal conductivity, and the underside of the substrate holder (2) and the bottom surface of the bearing opening (20) having such a shape, that, when only one of the two gases is used, the surface temperature of the substrate (9) resting on the substrate holder (2) has a rotationally symmetrical lateral inhomogeneity that can be compensated and overcompensated by changing the composition of the gas stream.

13. The apparatus according to claim 12 characterized in that a bottom (21) of the bearing recess (20) has a substantially rotationally symmetrical non-planarity, and in particular is curved.

14. The apparatus according to claim 13 characterized in that the underside of the substrate holder (2), lying opposite the bottom (21) of the bearing recess (20), has a substantially rotationally symmetrical structure deviating from a plane, and in particular is curved.

15. The apparatus according to claim 12 characterized in that the substrate holder (2) is thinner at the center than at the edge.

16. The apparatus according to claim 12 characterized in that the substrate (9) lies in a recess (22) in the upper side of the substrate holder (2) that is defined by a peripheral web (23).
